(19) United States
(12) Patent Application Publication
(10) Pub. No.: US 2024/0147696 A1
(43) Pub. Date: May 2, 2024

(54) SEMICONDUCTOR MEMORY DEVICE

(71) Applicant: Samsung Electronics Co., Ltd., Suwon-si (KR)

(72) Inventor: Ji Ho PARK, Suwon-si (KR)

(73) Assignee: Samsung Electronics Co., Ltd., Suwon-si (KR)

(21) Appl. No.: 18/221,133

(22) Filed: Jul. 12, 2023

(30) Foreign Application Priority Data
Oct. 27, 2022 (KR) 10-2022-0139808

(51) Int. Cl. H10B 12/00

(52) U.S. Cl. CPC H10B 12/315; H10B 12/482; H10B 12/488; H10B 12/50

(57) ABSTRACT

A semiconductor memory device includes a substrate including a cell region and a connecting region around the cell region, a cell active region defined by a cell element isolation layer in the cell region, a connecting element isolation layer in the connecting region, a word line structure extending in a first horizontal direction, and a dummy active region disposed between the cell element isolation layer and the connecting element isolation layer. The word line structure includes a gate electrode and a gate capping layer. The gate electrode includes a first portion not overlapping the gate capping layer in the first horizontal direction, and a second portion overlapping the gate capping layer in the first horizontal direction. The second portion overlaps the dummy active region in a vertical direction.

### CROSS-REFERENCE TO RELATED APPLICATION

This application claims priority to Korean Patent Application No. 10-2022-0139808 filed on Oct. 27, 2022 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a semiconductor memory device.

### 2. Description of the Related Art

As semiconductor elements become increasingly highly integrated, individual circuit patterns are becoming finer to implement more semiconductor elements in the same area. That is, as the degree of integration of semiconductor elements increases, design rules for components of the semiconductor elements decrease.

On the other hand, in highly scaled semiconductor elements, a process of forming a plurality of gate electrodes and contacts connected to the plurality of gate electrodes becomes increasingly complex and difficult.

### SUMMARY

Aspects of the present disclosure provide a semiconductor memory device having improved reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a semiconductor memory device includes a substrate which includes a cell region and a connecting region around the cell region, a cell active region which is defined by a cell element isolation layer in the cell region, a connecting element isolation layer which is placed in the connecting region, a word line structure which is buried in the cell region and the connecting region and extends in a first horizontal direction, a bit line structure which is disposed on the substrate and extends in a second horizontal direction intersecting the first horizontal direction, a capacitor structure disposed on the cell region and connected to the cell active region, and a dummy active region disposed between the cell element isolation layer and the connecting element isolation layer. The word line structure includes a gate electrode and a gate capping layer. The gate electrode includes a first portion that does not overlap the gate capping layer in the first horizontal direction, and a second portion that is disposed on the first portion and overlaps the gate capping layer in the first horizontal direction. The second portion overlaps the dummy active region in a vertical direction intersecting the first and second horizontal directions.

According to an aspect of the present disclosure, a semiconductor memory device includes a substrate which includes an edge region, and a center region defined by the edge region, a cell active region which is disposed on the center region and defined by a cell element isolation layer, a plurality of word line structures which are buried in the substrate, extend in a first horizontal direction, and are spaced apart in a second horizontal direction intersecting the first horizontal direction, a plurality of bit line structures which are disposed on the substrate, extend in the second horizontal direction, and are spaced apart in the first horizontal direction, a capacitor structure disposed on the substrate and connected to the cell active region, and a dummy active region disposed on the edge region. Each word line structure of the plurality of word line structures includes a gate electrode including a first region disposed on the center region and a second region disposed on the edge region, and a gate capping layer disposed on the first region of the gate electrode. An upper surface of the second region of the gate electrode is coplanar with an upper surface of the gate capping layer. The second region of the gate electrode overlaps the dummy active region in a vertical direction that intersects the first and second horizontal directions.

According to an aspect of the present disclosure, a semiconductor memory device includes a substrate which includes a cell region, a core region defined around the cell region, and a connecting region between the cell region and the core region, the cell region including an edge region, and a center region defined by the edge region, a cell element isolation layer disposed on the center region of the cell region, a connecting element isolation layer in the connecting region, a word line structure which is buried in the cell region and the connecting region and extends in a first horizontal direction, the word line structure including a gate electrode, a gate capping conductive layer, and a gate capping insulating layer, and the gate electrode including a first portion that does not overlap the gate capping conductive layer and the gate capping insulating layer in the first horizontal direction, and a second portion that overlaps the gate capping conductive layer and the gate capping insulating layer in the first horizontal direction, a bit line structure which is disposed on the substrate and extends in a second horizontal direction intersecting the first horizontal direction, a capacitor structure connected to the active region and disposed on the cell region, a peripheral circuit element disposed on the core region, a word line contact which is connected to the second portion of the gate electrode and the peripheral circuit element on the connecting region, and does not completely overlap the gate capping conductive layer in the first horizontal direction, and a dummy active region disposed between the cell element isolation layer and the connecting element isolation layer on the edge region, and a cell active region except the dummy active region on the center region. The gate capping conductive layer and the gate capping insulating layer are not disposed in the edge region. The second portion overlaps the dummy active region in a vertical direction intersecting the first and second horizontal directions.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a semiconductor memory device according to some embodiments of the present disclosure.

FIG. 2 is a plan view of a semiconductor memory device according to some embodiments of the disclosure.

FIG. 3 is a cross-sectional view taken along line A-A of FIG. 2.

FIG. 4 is a cross-sectional view taken along line B-B of FIG. 2.

FIG. 5 is a cross-sectional view taken along line C-C of FIG. 2.

FIGS. 6 to 12 are exemplary diagrams of a semiconductor memory device according to some embodiments.

FIGS. 13 to 20 are intermediate stage diagrams for explaining the method of manufacturing the semiconductor memory device according to some embodiments.

FIGS. 21 to 25 are intermediate stage diagrams for explaining the method of manufacturing the semiconductor memory device according to some embodiments.

### DETAILED DESCRIPTION OF THE EMBODIMENTS

Hereinafter, embodiments according to the technical concept of the present disclosure will be described with reference to the accompanying drawings.

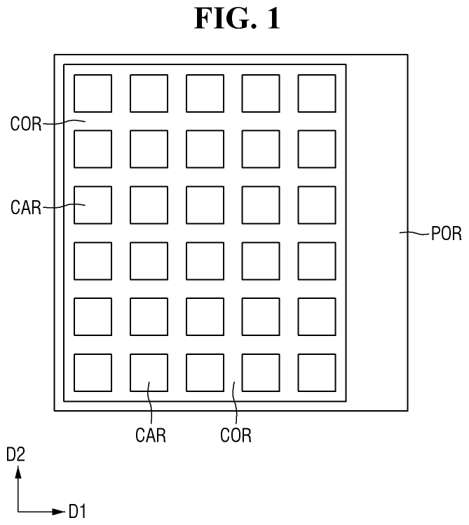

Although diagrams relating to a semiconductor memory device according to some embodiments show a dynamic random access memory (DRAM) as an example, the embodiment is not limited thereto. The semiconductor memory device according to several embodiments of the present disclosure will be described below with reference to FIGS. 1 to 5.

FIG. 1 is a plan view of a semiconductor memory device according to some embodiments of the present disclosure.

Referring to FIG. 1, the semiconductor memory device according to some embodiments may include cell regions CAR. The cell regions CAR may be regions including a plurality of memory cells. Each of the plurality of cell regions CAR may constitute one unit cell block. The cell regions CAR may be spaced apart from each other in a first direction D1 (i.e., a first horizontal direction) and a second direction D2 (i.e., a second horizontal direction), and a core region COR may be provided between the cell regions CAR. The core region COR may be a region in which a sense amplifier and a write driver are provided. A peripheral circuit region POR may be provided on one side of the cell regions CAR. The peripheral circuit region POR may include a row decoder, a column decoder, and the like. Although the peripheral circuit region POR is shown on one side of the cell regions CAR, the peripheral circuit region POR may be provided on the other side of the cell regions CAR.

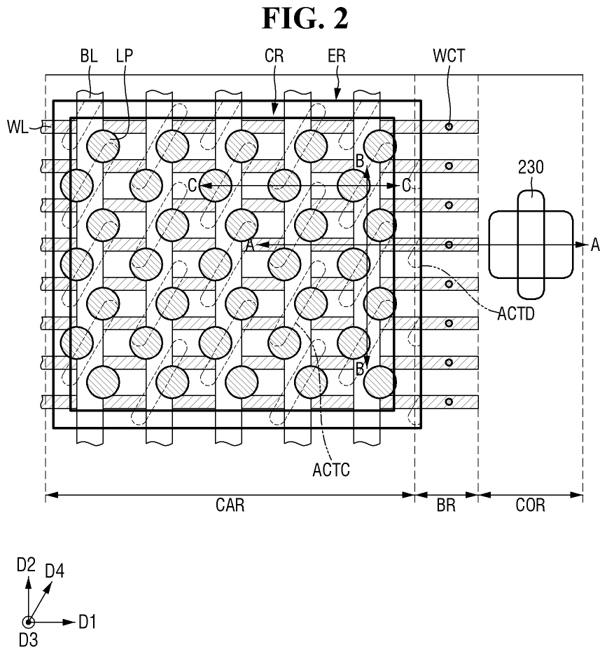

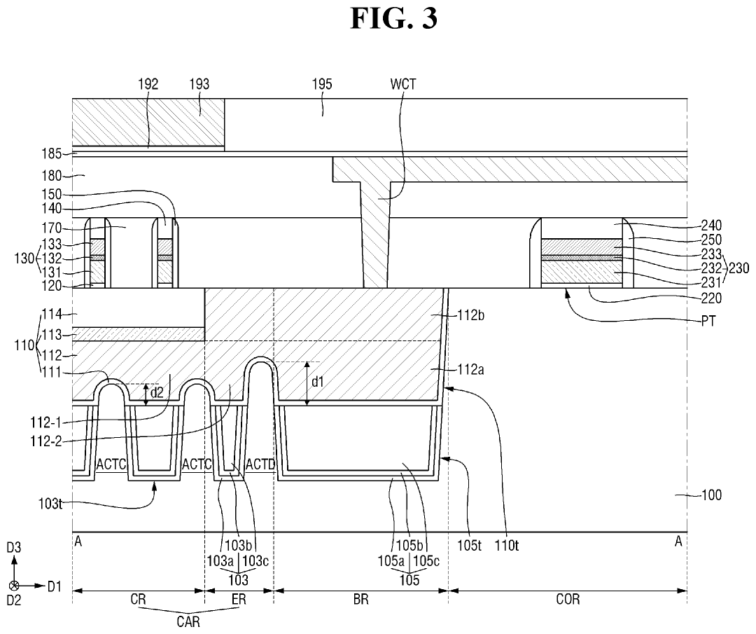

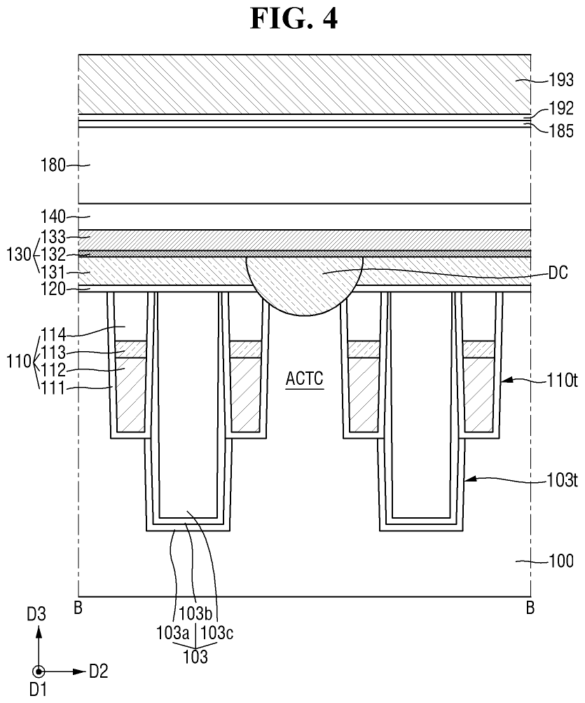

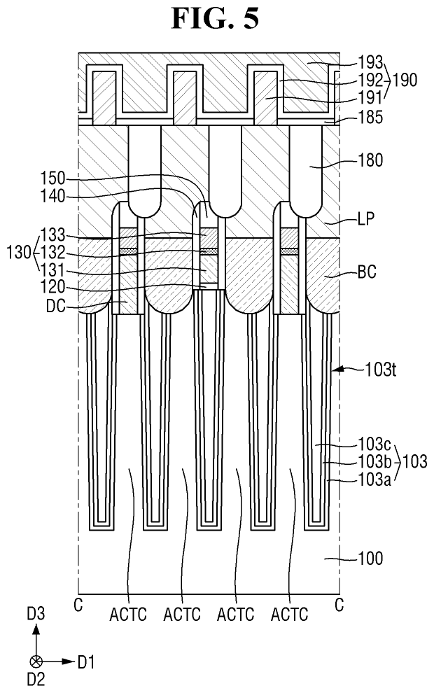

FIG. 2 is a plan view of a semiconductor memory device according to some embodiments of the disclosure. FIG. 3 is a cross-sectional view taken along line A-A of FIG. 2. FIG. 4 is a cross-sectional view taken along line B-B of FIG. 2. FIG. 5 is a cross-sectional view taken along line C-C of FIG. 2.

Referring to FIGS. 2 to 5, a substrate 100 that includes a cell region CAR, a connecting region BR, and a core region COR may be provided.

The cell region CAR may be a region in which a plurality of memory cells are provided. The connecting region BR may be provided around the cell region CAR. Specifically, the connecting region BR may be provided between the core region COR and the cell region CAR. The connecting region BR may be a region for connecting the structure placed in the cell region CAR and the structure of the core region COR with each other. The cell region CAR may include an edge region ER and a center region CR. The center region CR may be defined by the edge region ER. A second region 112_2 of the gate electrode 112, which will be described later, may be placed in the substrate 100 of the edge region ER. A first region 112_1 of the gate electrode 112, which will be described later, may be placed in the substrate 100 of the center region CR.

The substrate 100 may be, for example, a silicon single crystal substrate or an SOI (Silicon on Insulator) substrate. The present invention is not limited thereto. In some embodiments, the substrate 100 may include or may be formed of silicon germanium, silicon germanium on insulator (SGOI), indium antimonide, lead telluride, indium arsenide, indium phosphide, gallium arsenide or gallium antimonide.

A cell element isolation layer 103 may be provided inside the substrate 100 of the cell region CAR. The cell element isolation layer 103 may include a first cell liner 103a, a second cell liner 103b, and a cell buried insulating layer 103c. The first cell liner 103a may be conformally formed on inner side walls and a bottom surface of a cell trench 103t formed in the substrate 100 of the cell region CAR. The cell buried insulating layer 103c may fill the cell trench 103t. The second cell liner 103b may be interposed between the first cell liner 103a and the cell buried insulating layer 103c.

A connecting element isolation layer 105 may be provided inside the substrate 100 of the connecting region BR. The connecting element isolation layer 105 may include a first connecting liner 105a, a second connecting liner 105b, and a connecting buried insulating layer 105c. The first connecting liner 105a may be conformally formed on inner side walls and bottom surfaces of a connecting trench 105t formed inside the substrate 100 of the connecting region BR. The connecting buried insulating layer 105c may fill the connecting trench 105t. The second connecting liner 105b may be interposed between the first connecting liner 105a and the connecting buried insulating layer 105c.

The first cell liner 103a and the first connecting liner 105a may include or may be formed of the same material. For example, the first cell liner 103a and the first connecting liner 105a may each include or may be formed of silicon oxide. The second cell liner 103b and the second connecting liner 105b may include or may be formed of the same material. For example, the second cell liner 103b and the second connecting liner 105b may each include or may be formed of silicon nitride. The cell buried insulating layer 103c and the connecting buried insulating layer 105c may include or may be formed of the same material. For example, the cell buried insulating layer 103c and the connecting buried insulating layer 105c may each include or may be formed of silicon oxide.

The cell region CAR may include a plurality of active regions ACTC and ACTD. The plurality of active regions ACTC and ACTD may be defined by the cell element isolation layer 103 and/or the connecting element isolation layer 105. As shown in FIG. 2, as the design rule of the semiconductor memory device decreases, a plurality of active regions ACTC and ACTD may each be placed in a bar shape of a diagonal line or an oblique line. For example, the active regions ACTC and ACTD may extend in a fourth direction D4.

The plurality of active regions ACTC and ACTD may be arranged parallel to each other in the first direction D1. An end of one active region ACTC and ACTD may be arranged to be adjacent to the center of another adjoining active region ACTC and ACTD. In this specification, the first direction D1, the second direction D2, the third direction D3, and the fourth direction D4 may intersect each other. The first direction D1, the second direction D2 and the third direction D3 may be substantially perpendicular to each other. The fourth direction D4 may be placed on the same plane as the first direction D1 and the second direction D2. That is, the fourth direction D4 may be any direction between the first direction D1 and the second direction D2. In some embodiments, the first and second directions D1 and D2, and the fourth direction D4 may be parallel to an upper surface of the substrate 100 or an lower surface of the substrate 100. The third direction D3 (i.e., a vertical direction) may be perpendicular to the upper or lower surface of the substrate 100.

In some embodiments, the active regions ACTC and ACTD may include a cell active region ACTC and a dummy active region ACTD. The cell active region ACTC may be placed in the center region CR of the cell region CAR. The cell active region ACTC may be defined by the cell element isolation layer 103. The dummy active region ACTD may be placed in the edge region ER of the cell region CAR. The dummy active region ACTD may be defined by the cell element isolation layer 103 and the connecting element isolation layer 105. The dummy active region ACTD may be provided, but is not limited to, between the cell element isolation layer 103 and the connecting element isolation layer 105. In some embodiments, the dummy active region ACTD may refer to an active region in the edge region ER of the cell region CAR. The dummy active region ACTD may have a shape of a partial active region of the cell active region ACTC, without being connected to a capacitor.

A semiconductor memory device according to some embodiments may include various contact arrangements formed on the active regions ACTC and ACTD. Various contact arrangements may include, for example, a direct contact (DC), a buried contact (BC), a landing pad (LP), and the like.

Here, the direct contact DC may refer to a contact that electrically connects the cell active region ACTC to the bit line BL. The buried contact BC may refer to a contact that connects the cell active region ACTC to the capacitor lower electrode 191. Due to the arrangement structure, a contact area between the buried contact BC and the cell active region ACTC may be small. Therefore, a conductive landing pad LP may serve to expand the contact area with the cell active region ACTC and expand the contact area with the capacitor lower electrode 191. In some embodiments, the capacitor lower electrode 191 may be connected to the cell active region ACTC via the conductive landing pad LP and the buried contact BC. In some embodiments, the capacitor lower electrode 191 may not be connected to the dummy active region ACTD.

The landing pad LP may be placed between the cell active region ACTC and the buried contact BC, or may be placed between the buried contact BC and the capacitor lower electrode 191. In the semiconductor memory device according to some embodiments, a landing pad LP may be placed between the buried contact BC and the capacitor lower electrode 191. By increasing the contact area through the introduction of the landing pad LP, the contact resistance between the cell active region ACTC and the capacitor lower electrode 191 may decrease.

Word lines WL may be buried inside the substrate 100 of the cell region CAR and the connecting region BR. The word lines WL may cross a plurality of active regions ACTC and ACTD. The word lines WL may extend in the first direction D1. The word lines WL may be spaced apart from each other in the second direction D2. The word lines WL may be buried in the substrate 100 and extend in the first direction D1. Although not shown, a doping region may be formed in the cell active regions ACTC between the word lines WL. The doping region may be doped with N-type impurities.

A semiconductor memory device according to some embodiments may include the plurality of word line structures 110. Each of the plurality of word line structures 110 may be buried inside the substrate 100 and extend in the first direction D1. The plurality of word line structures 110 may be spaced apart from each other in the second direction D2.

Each of the plurality of word line structures 110 may include a gate insulating layer 111, a gate electrode 112 and gate capping layers 113 and 114. The gate electrode 112 of the word line structure 110 may correspond to the word line WL of the semiconductor memory device according to some embodiments. Each of the plurality of word line structures 110 may be provided inside a gate trench 110t formed inside the substrate 100.

The gate insulating layer 111 extends along the inner side walls and the bottom surface of the gate trench 110t. The gate insulating layer 111 may extend along the profile of at least a part of the gate trench 110t. For example, the gate insulating layer 111 may be conformally formed in at least a part of the gate trench 110t. The gate insulating layer 111 may include or may be formed of, for example, at least one of silicon oxide, silicon nitride, silicon oxynitride and a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The gate electrode 112 may be placed on the gate insulating layer 111. The gate electrode 112 may fill a part of the gate trench 110t. The gate capping layers 113 and 114 may be placed on the gate electrode 112. The gate capping layers 113 and 114 may fill the gate trench 110t that remains after the gate electrode 112 is formed.

In some embodiments, the gate capping layers 113 and 114 may include a gate capping conductive layer 113 and a gate capping insulating layer 114. The gate capping conductive layer 113 and the gate capping insulating layer 114 may be sequentially stacked. That is, the gate capping insulating layer 114 is placed on the gate capping conductive layer 113. The gate capping conductive layer 113 may include or may be formed of, for example, but is not limited to, polysilicon or polysilicon-germanium. The gate capping insulating layer 114 may include or may be formed of, for example, at least one of silicon nitride (SiN), silicon oxynitride (SiON), silicon oxide (SiO₂), silicon carbonitride (SiCN), silicon oxycarbonitride (SiOCN), and combinations thereof.

In FIG. 3, the gate electrode 112 may include a first portion 112a and a second portion 112b.

The first portion 112a of the gate electrode 112 does not overlap the gate capping layers 113 and 114 in the first direction D1. The second portion 112b of the gate electrode 112 overlaps the gate capping layers 113 and 114 in the first direction D1. The second portion 112b of the gate electrode 112 may be provided on the first portion 112a of the gate electrode 112. An upper surface of the second portion 112b of the gate electrode 112 may be located in the same plane as the upper surfaces of the gate capping layers 113 and 114. An upper surface of the second portion 112b of the gate electrode 112 may be located in the same plane as an upper surface of the gate capping insulating layer 114. However, the technical idea of the present disclosure is not limited thereto.

A part of the second portion 112b of the gate electrode 112 may be provided in the connecting region BR. Another part of the second portion 112b of the gate electrode 112 may be placed in the cell region CAR. Specifically, a part of the second portion 112b of the gate electrode 112 is placed in the connecting region BR, and another part of the second portion 112b of the gate electrode 112 may be placed in the edge region ER.

The second portion 112b of the gate electrode 112 overlaps the dummy active region ACTD in the third direction D3. In terms of cross section, the second portion 112b of the gate electrode 112 may cover the dummy active region ACTD. The dummy active region ACTD does not completely overlap the gate capping layers 113 and 114 in the third direction D3. The second portion 112b of the gate electrode 112 does not overlap the dummy active region ACTD in the first direction D1. Also, the dummy active region ACTD may not overlap the gate capping layers 113 and 114 in the first direction D1. In some embodiments, the second portion 112b of the gate electrode 112 may overlap a part of the cell active region ACTC in the third direction D3, but is not limited thereto.

In some embodiments, the gate electrode 112 may include a first region 112_1 and a second region 112_2. The first region 112_1 and the second region 112_2 of the gate electrode 112 may each be placed in the substrate 100 of the cell region CAR.

The first region 112_1 and the second region 112_2 of the gate electrode 112 may be aligned with each other in the first direction D1. Specifically, the first region 112_1 of the gate electrode 112 is placed inside the substrate 100 of the center region CR. The second region 112_2 of the gate electrode 112 is placed in the edge region ER. The first region 112_1 of the gate electrode 112 completely overlaps the gate capping layers 113 and 114 in the third direction D3. That is, the gate capping layers 113 and 114 are placed on the first region 112_1 of the gate electrode 112. The second region 112_2 of the gate electrode 112 does not completely overlap the gate capping layers 113 and 114 in the third direction D3. The second region 112_2 of the gate electrode 112 overlaps the dummy active region ACTD in the third direction D3. The second region 112_2 of the gate electrode 112 overlaps a part of the dummy active region ACTD in the first direction D1. The upper surface of the second region 112_2 of the gate electrode 112 may be placed on the same plane as (i.e., may be coplanar with) the upper surfaces of the gate capping layers 113 and 114. That is, the upper surface of the second region 112_2 of the gate electrode 112 may be placed on the same plane as the upper surface of the gate capping insulating layer 114.

The gate electrode 112 may include or may be formed of at least one of a metal, a metal alloy, a conductive metal nitride, a conductive metal carbonitride, a conductive metal carbide, a metal silicide, a doped semiconductor material, a conductive metal oxynitride, and a conductive metal oxide. The gate electrode 112 may include or may be formed of, for example, but is not limited to, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and combinations thereof. The first portion 112a and the second portion 112b of the gate electrode 112 may be formed of the same material.

In some embodiments, the size of the dummy active region ACTD may be greater than the size of the cell active region ACTC. As an example, a first height d1 in the third direction D3 of the dummy active region ACTD placed in the gate electrode 112 is greater than a second height d2 in the third direction D3 of the cell active region ACTC placed in the gate electrode 112. In a highly scaled semiconductor memory device, the dummy active region ACTD placed in the edge region ER may be merged with another adjacent dummy active region ACTD. That is, the size of the dummy active region ACTD may be greater than the size of the cell active region ACTC. The dummy active region ACTD may be less recessed than the cell active region ACTC when forming the gate trench 110t. Accordingly, the first height d1 may be greater than the second height d2. Furthermore, although not shown, the width of the dummy active region ACTD may be greater than the width of the cell active region ACTC from a planar viewpoint. For example, the first height d1 of a first upper portion of the dummy active region ACTD may be higher than the second height d2 of a second upper portion of the cell active region ACTC. The first upper portion of the dummy active region ACTD and the second upper portion of the cell active region ACTC may be surrounded by the gate electrode 112. The first and second heights d1 and d2 may be measured in the third direction D3 relative to a bottom surface of the gate electrode 112 that may contact or may be adjacent to an upper surface of the cell buried insulating layer 103c and an upper surface of the connecting buried insulating layer 105c. However, the technical idea of the present disclosure is not limited thereto.

A cell buffer layer 120 may be provided on the substrate 100 of the cell region CAR. Although not shown, the cell buffer layer 120 may include first to third insulating layers that are sequentially stacked. The second insulating layer may include or may be formed of a material having etch selectivity with respect to the first and third insulating layers. For example, the second insulating layer may include or may be formed of silicon nitride, and the first and third insulating layers may include or may be formed of silicon oxide.

Bit lines BL may be placed on the substrate 100. The bit lines BL may be placed on the cell buffer layer 120. The bit lines BL may cross the word line WL. The bit lines BL may extend in the second direction D2. Also, the bit lines BL may be spaced apart from each other in the first direction D1. The bit line BL may correspond to the bit line structure 130.

The bit line structure 130 may include a bit line lower electrode 131, a bit line middle electrode 132, and a bit line upper electrode 133, which are sequentially stacked. The bit line lower electrode 131 may include or may be formed of impurity-doped polysilicon. The bit line middle electrode 132 may include or may be formed of TiSiN. The bit line upper electrode 133 may include or may be formed of tungsten (W). However, the technical idea of the present disclosure is not limited thereto. A bit line capping pattern 140 may be placed on the bit line structure 130. The bit line capping pattern 140 may include or may be formed of silicon nitride.

Bit line spacers 140 may be placed on side walls of the bit line structure 130 and side walls of the bit line capping pattern 150. In FIG. 5, the bit line spacer 140 that is disposed on a sidewall of the direct contact DC may be placed on the substrate 100 and the cell element isolation layer 103. However, the bit line spacer 140 that is not disposed on a sidewall of the direct contact DC may be placed on the cell buffer layer 120.

As shown, although the bit line spacer 150 may be a single layer, the technical idea of the disclosure is not limited thereto. Of course, the bit line spacer 150 may be a multiple layer. The bit line spacer 150 may include or may be formed of, for example, but is not limited to, one of a silicon oxide layer, a silicon nitride layer, a silicon oxynitride layer (SiON), a silicon oxycarbonitride layer (SiOCN), air, and combinations thereof.

The cell buffer layer 120 may be interposed between the bit line structure 130 and the cell element isolation layer 103, and between the bit line spacer 150 and the substrate 100.

The bit line BL may be electrically connected to the doping region of the cell active region ACTC by a direct contact DC. The direct contact DC may be formed of, for example, polysilicon doped with impurities.

A buried contact BC may be placed between a pair of adjacent bit lines BL. The buried contacts BC may be spaced apart from each other. The buried contact BC may include or may be formed of at least one of impurity doped polysilicon, a conductive silicide compound, a conductive metal nitride and a metal. The buried contact BC may have island shapes that are spaced apart from each other in a plan view. The buried contact BC may penetrate the cell buffer layer 120 and abut on the doping regions of the cell active region ACTC.

A landing pad LP may be formed on the buried contact BC. The landing pad LP may be electrically connected to the buried contact BC. The landing pad LP may overlap a part of the upper surface of the bit line BL. The landing pad LP may include or may be formed of, for example, at least one of an impurity-doped semiconductor material, a conductive silicide compound, a conductive metal nitride, a conductive metal carbide, a metal and a metal alloy.

A fence pattern 170 may be placed on the substrate 100, the cell element isolation layer 103 and the connecting element isolation layer 105. The fence pattern 170 may be placed on the word line structure 110. Also, the fence pattern 170 may be placed on the substrate 100 of the core region COR. The fence pattern 170 may be formed to overlap the word line structure 110 formed inside the substrate 100. The fence pattern 170 may be placed between the bit line structures 130 extending in the second direction D2. The fence pattern 170 may include or may be formed of, for example, at least one of silicon oxide, silicon nitride, silicon oxynitride, and combinations thereof.

A pad isolation insulating layer 180 may be formed on the landing pad LP and the bit line structure 130. For example, the pad isolation insulating layer 180 may be placed on the bit line capping pattern 140. The pad isolation insulating layer 180 may define regions of the landing pad LP that form a plurality of isolated regions. Also, the pad isolation insulating layer 180 may not cover the upper surface of the landing pad LP. The pad isolation insulating layer 180 may extend to the connecting region BR and the core region COR. The pad isolation insulating layer 180 may be placed on the second portion 112b of the gate electrode 112. The pad isolation insulating layer 180 may be placed on the peripheral circuit element PT.

The pad isolation insulating layer 180 may include or may be formed of an insulating material, and electrically isolate the plurality of landing pads LP from each other. For example, the pad isolation insulating layer 180 may include or may be at least one of a silicon oxide layer, a silicon nitride layer, a silicon oxynitride layer, a silicon oxycarbonitride layer, and a silicon carbonitride layer.

An etching stop layer 185 may be placed on the pad isolation insulating layer 180 and the landing pad LP. The etching stop layer 185 may include or may be at least one of a silicon nitride layer, a silicon carbonitride layer, a silicon boron nitride layer (SiBN), a silicon oxynitride layer, and a silicon oxycarbide layer.

A capacitor structure 190 may be placed on the landing pad LP. The capacitor structure 190 may be electrically connected to the landing pad LP. A part of the capacitor structure 190 may be placed inside the etching stop layer 185. The capacitor structure 190 includes a capacitor lower electrode 191, a capacitor dielectric layer 192, and a capacitor upper electrode 193.

The capacitor lower electrode 191 may be placed on the landing pad LP. The capacitor lower electrode 191 is shown to have a pillar shape, but is not limited thereto. The capacitor lower electrode 191 may have a cylinder shape. A capacitor dielectric layer 192 is formed on the capacitor lower electrode 191. The capacitor dielectric layer 192 may be formed along a profile of the capacitor lower electrode 191. A capacitor upper electrode 193 is formed on the capacitor dielectric layer 192. The capacitor upper electrode 193 may cover the outer side walls of the capacitor lower electrode 191.

As an example, the capacitor dielectric layer 192 may be placed in a portion that vertically overlaps the capacitor upper electrode 193. As another example, unlike the shown example, the capacitor dielectric layer 192 may include a portion that vertically overlaps the capacitor upper electrode 193, and a portion that does not vertically overlap the capacitor upper electrode 193. That is, the portion of the capacitor dielectric layer 192 that does not vertically overlap the capacitor upper electrode 193 is a portion that is not covered with the capacitor upper electrode 193.

The capacitor lower electrode 191 and the capacitor upper electrode 193 may include or may be formed of, for example, but are not limited to, a doped semiconductor material, a conductive metal nitride (e.g., titanium nitride, tantalum nitride, niobium nitride or tungsten nitride, etc.), a metal (e.g., ruthenium, iridium, titanium or tantalum, etc.), or a conductive metal oxide (e.g., iridium oxide or niobium oxide, etc.).

The capacitor dielectric layer 192 may include or may be formed of, for example, but is not limited to, one of silicon oxide, silicon nitride, silicon oxynitride, a high dielectric constant material, and combinations thereof. In the semiconductor memory device according to some embodiments, the capacitor dielectric layer 192 may include a stacked layer structure in which zirconium oxide, aluminum oxide, and zirconium oxide are sequentially stacked. In the semiconductor memory device according to some embodiments, the capacitor dielectric layer 192 may include or may be formed of a dielectric layer including hafnium (Hf). In semiconductor memory device according to some embodiments, the capacitor dielectric layer 192 may have a stacked layer structure of a ferroelectric material layer and a paraelectric material layer.

In some embodiments, a peripheral circuit element PT may be provided on the substrate 100 of the core region COR.

Although not shown, a core element isolation layer may be provided inside the substrate 100 of the core region COR. The core element isolation layer may define a core active region. The peripheral circuit element PT may be provided on the core active region.

The peripheral circuit element PT may include a core gate insulating layer 220, a core gate structure 230, a core gate capping pattern 240, and a core gate spacer 250. The components of the core gate structure 230 may each be placed at substantially the same level as the components of the bit line structure 130. The core gate insulating layer 220 may be placed at substantially the same level as the cell buffer layer 120. The core gate capping pattern 240 may be placed at substantially the same level as the bit line capping pattern 140.

The core gate insulating layer 220 may extend along the substrate 100 of the core region COR. The core gate insulating layer 220 may include or may be formed of, for example, silicon oxide, silicon nitride, silicon oxynitride or a high dielectric constant material having a higher dielectric constant than silicon oxide.

The core gate structure 230 may include first to third conductive layers 231, 232 and 233 that are sequentially stacked. A first conductive layer 231 may be placed on the core gate insulating layer 220. A second conductive layer 232 may be placed on the first conductive layer 231. A third conductive layer 233 may be placed on the second conductive layer 232. The first conductive layer 231 may be formed by the same process as that of the bit line lower electrode 131. The second conductive layer 232 may be formed by the same process as that of the bit line middle electrode 132. The third conductive layer 233 may be formed by the same process as that of the bit line upper electrode 133. Therefore, a thickness of the first conductive layer 231 in the third direction D3 may be substantially the same as a thickness of the bit line lower electrode 131 in the third direction D3. Similarly, a thickness of the second conductive layer 232 in the third direction D3 may be substantially the same as a thickness of the bit line middle electrode 132 in the third direction D3. A thickness of the third conductive layer 233 in the third direction D3 may be substantially the same as a thickness of the bit line upper electrode 133 in the third direction D3.

The first conductive layer 231 may include or may be formed of polysilicon doped with impurities. The second conductive layer 232 may include or may be formed of TiSiN. The third conductive layer 233 may include or may be formed of tungsten (W). However, the technical idea of the present disclosure is not limited thereto.

A core gate capping pattern 240 is placed on the core gate structure 230. The core gate capping pattern 240 may be formed by substantially the same process as that of the bit line capping pattern 140. Accordingly, a thickness of the core gate capping pattern 240 in the third direction D3 may be substantially the same as a thickness of the bit line capping pattern 140 in the third direction D3. The core gate capping pattern 240 may include or may be formed of, for example, silicon nitride.

A core gate spacer 250 may be placed on side walls of the core gate structure 230 and side walls of the core gate capping pattern 240. The core gate spacer 250 may include or may be formed of, for example, but is not limited to, one of a silicon oxide layer, a silicon nitride layer, a silicon oxynitride layer (SiON), a silicon oxycarbonitride layer (SiOCN), air, and combinations thereof.

The semiconductor memory device according to some embodiments may further include a word line contact WCT.

The word line contact WCT may be formed on the substrate 100 of the connecting region BR. One end of the word line contact WCT may be connected to the gate electrode 112. The other end of the word line contact WCT may be connected to the peripheral circuit element PT.

In some embodiments, the word line contact WCT may be connected to the second portion 120b of the gate electrode 112. The word line contact WCT may be connected to the upper surface of the second portion 120b of the gate electrode 112. For example, the word line contact WCT may contact the upper surface of the second portion 120b of the gate electrode 112. In some embodiments, the word line contact WCT may not overlap the gate capping layers 113 and 114 in the first direction D1. The word line contact WCT may not overlap the gate capping insulating layer 114 and the gate capping conductive layer 113 in the first direction D1. A part of the word line contact WCT may overlap the gate capping insulating layer 114 in the first direction D1. Also in this case, the word line contact WCT may not completely overlap the gate capping conductive layer 113 in the first direction D1.

An interlayer insulating layer 195 may be placed on the etching stop layer 185. The interlayer insulating layer 195 may cover the side walls of the upper electrode 193. The interlayer insulating layer 195 may include or may be formed of an insulating material. For example, the interlayer insulating layer 195 may include or may be formed of, but is not limited to, silicon oxide.

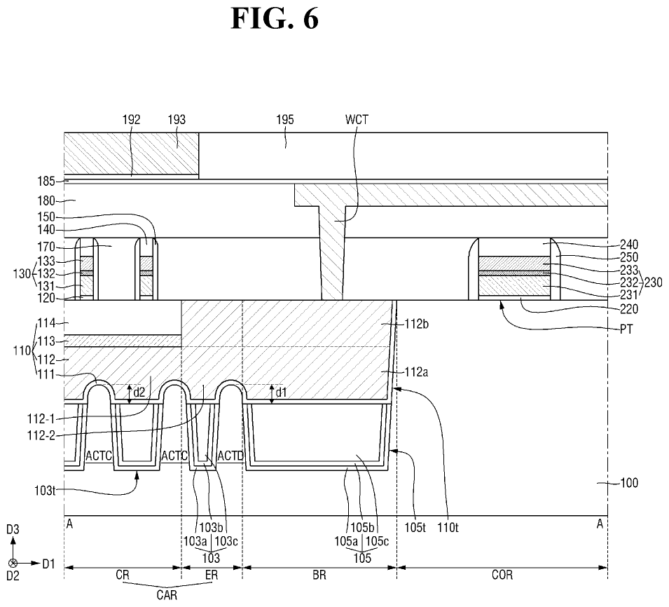

A semiconductor memory device according to some embodiments of the present disclosure will be described below with reference to FIGS. 6 to 12.

FIGS. 6 to 12 are exemplary diagrams of a semiconductor memory device according to some embodiments. For reference, FIGS. 6 to 12 may each be exemplary diagrams of a cross section taken along line A-A of FIG. 2. For convenience of explanation, the explanation will focus on points that are different from those explained using FIGS. 1 to 5.

Referring to FIG. 6, a first height d1 in the third direction D3 of the dummy active region ACTD placed inside the gate electrode 112 may be identical to a second height d2 in the third direction D3 of the cell active region ACTC placed inside the gate electrode 112.

In some embodiments, the dummy active region ACTD placed in the edge region ER may not be merged with another adjacent dummy active region ACTD. Therefore, the size of the dummy active region ACTD may be identical to the size of the cell active region ACTC. In this case, the dummy active region ACTD and the cell active region ACTC may be recessed at the same level when forming the gate trench 110t. Therefore, the first height d1 and the second height d2 may be identical to each other.

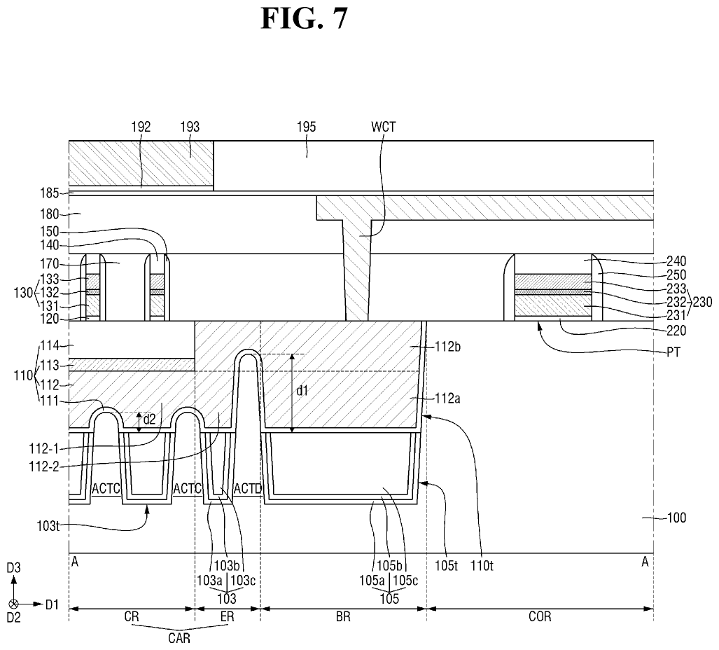

Referring to FIG. 7, at least a part of the dummy active region ACTD may overlap the gate capping layers 113 and 114 in the first direction D1. At least a part of the dummy active region ACTD is placed in the second portion 112b of the gate electrode 112. At least a part of the dummy active region ACTD may overlap the second portion 112b of the gate electrode 112 in the first direction D1.

According to some embodiments of the present disclosure, the level of the upper surface of the second portion 112b of the gate electrode 112 is higher than the level of the upper surface of the dummy active region ACTD inside the gate electrode 112. That is, even if the dummy active region ACTD is less recessed, the first portion 112a and the second portion 112b of the gate electrode 112 are electrically connected with each other. Therefore, the first portion 112a and the second portion 112b of the gate electrode 112 are not electrically shorted. Therefore, a semiconductor memory device with improved reliability may be manufactured.

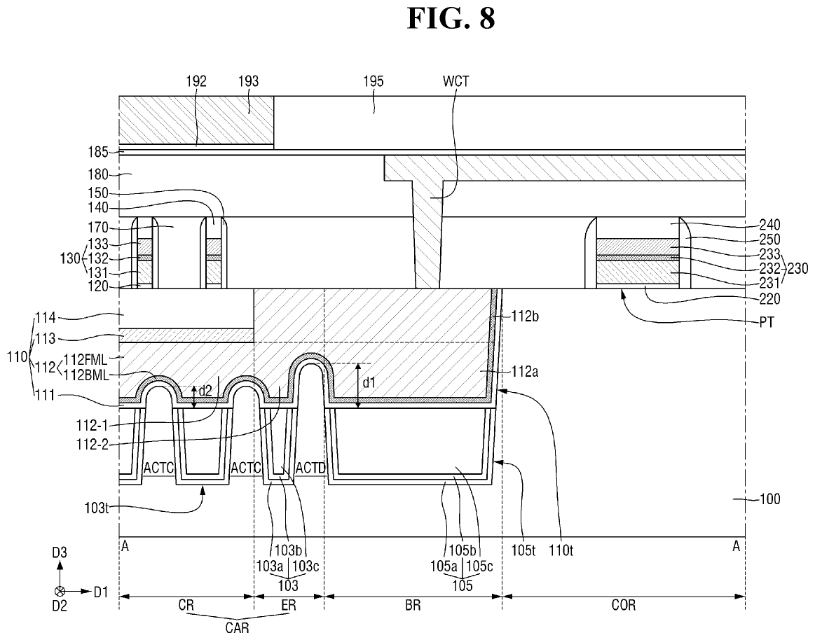

Referring to FIG. 8, the gate electrode 112 according to some embodiments may be formed of the multiple layers.

For example, the gate electrode 112 may include a gate electrode barrier layer 112BML and a gate electrode filling layer 112FML. The gate electrode barrier layer 112BML may be placed on the gate insulating layer 111. The gate electrode barrier layer 112BML may be formed conformally. The gate electrode filling layer 112FML may be placed on the gate electrode barrier layer 112BML. The gate electrode barrier layer 112BML may serve as a seed layer of the gate electrode filling layer 112FML.

The gate electrode barrier layer 112BML may include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) and a two-dimensional material (2D material).

The gate electrode filling layer 112FML may include, for example, at least one of aluminum (Al), copper (Cu), tungsten (W), cobalt (Co), ruthenium (Ru), silver (Ag), gold (Au), manganese (Mn), and molybdenum (Mo).

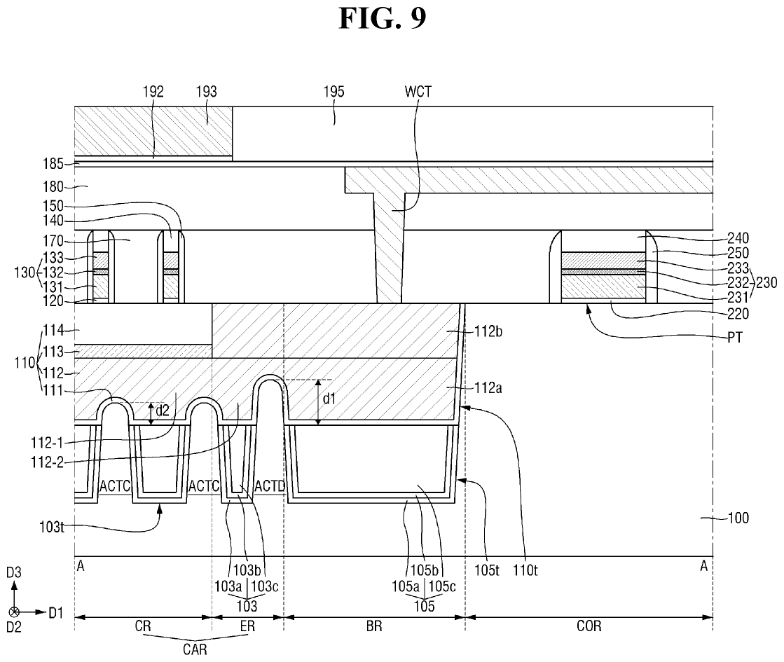

Referring to FIG. 9, the first portion 112a and the second portion 112b of the gate electrode 112 may be formed of different materials from each other.

In some embodiments, after the first portion 112a of the gate electrode 112 is formed, the second portion 112b may be formed. As an example, when both the first portion 112a and the second portion 112b of the gate electrode 112 are single layers, the first portion 112a and the second portion 112b of the gate electrode 112 may be formed of materials different from each other.

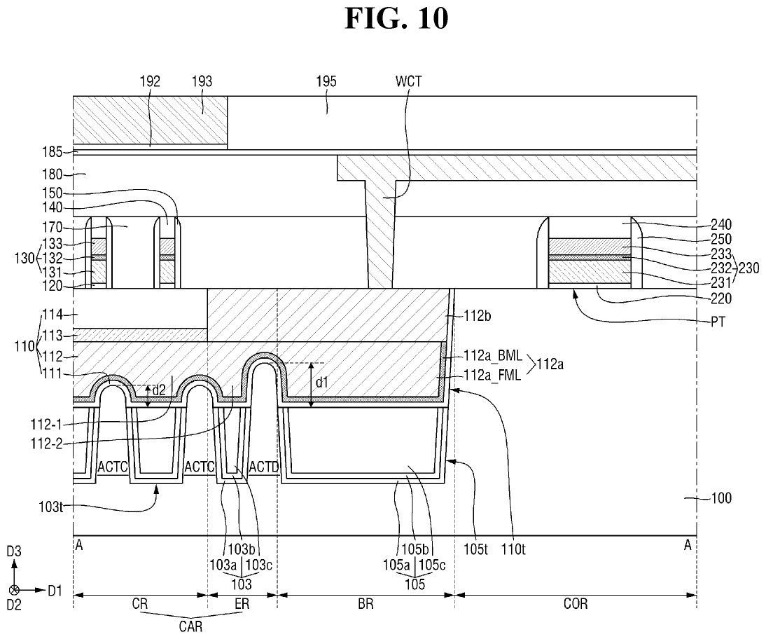

Referring to FIG. 10, the first portion 112a of the gate electrode 112 may be formed of the multiple layers, and the second portion 112b of the gate electrode 112 may be formed of a single layer.

For example, the first portion 112a of the gate electrode 112 may include a first barrier layer 112a_BML and a first filling layer 112a_FML. The first barrier layer 112a_BML is placed on the gate insulating layer 111. The first filling layer 112a_FML is placed on the first barrier layer 112a_BML. The first filling layer 112a_FML may be provided between the first barrier layer 112a_BML and the second portion 112b of the gate electrode 112.

The first barrier layer 112a_BML may include or may be formed of, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional material (2D material).

The first filling layer 112a_FML may include or may be formed of, for example, at least one of aluminum (Al), copper (Cu), tungsten (W), cobalt (Co), ruthenium (Ru), silver (Ag), gold (Au), manganese (Mn), and molybdenum (Mo).

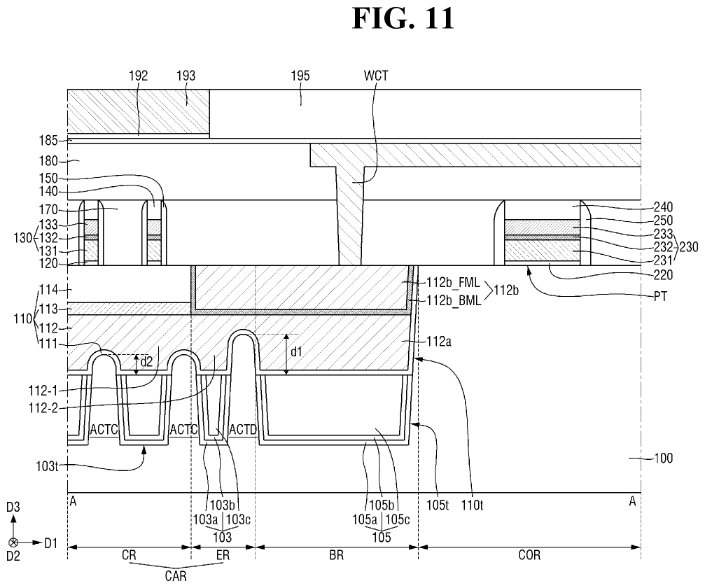

Referring to FIG. 11, the first portion 112a of the gate electrode 112 may be formed of a single layer, and the second portion 112b of the gate electrode 112 may be formed of the multiple layers.

For example, the second portion 112b of the gate electrode 112 may include a second barrier layer 112b_BML and a second filling layer 112b_FML. The second barrier layer 112b_BML is placed on the gate insulating layer 111 and the first portion 112a of the gate electrode 112. The second filling layer 112b_FML is placed on the second barrier layer 112b_BML.

The second barrier layer 112b_BML may include or may be formed of, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional material (2D material).

The second filling layer 112b_FML may include or may be formed of, for example, at least one of aluminum (Al), copper (Cu), tungsten (W), cobalt (Co), ruthenium (Ru), silver (Ag), gold (Au), manganese (Mn), and molybdenum (Mo).

Although not shown, both the first portion 112a and the second portion 112b of the gate electrode 112 may be formed of multiple layers. In this case, the first portion 112a of the gate electrode 112 and the second portion 112b of the gate electrode 112 may each include a barrier layer and a filling layer.

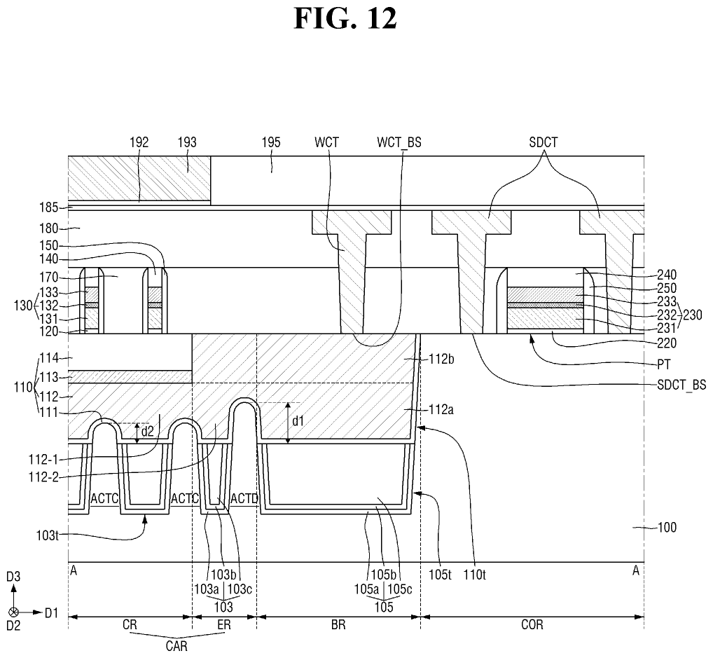

Referring to FIG. 12, a semiconductor memory device according to some embodiments may further include source/drain contacts SDCT.

The source/drain contacts SDCT may be disposed on the core region COR. The source/drain contacts SDCT may be disposed on the substrate 100 of the core region COR. The source/drain contacts SDCT may be disposed on at least one side of the peripheral circuit element PT. In FIG. 12, a pair of source/drain contacts SDCT are illustrated as being disposed on opposite sides of the peripheral circuit element PT, but the technical spirit of the present disclosure is not limited thereto. Unlike shown, the source/drain contacts SDCT may be disposed on only one side of the peripheral circuit element PT.

Although not shown, source/drain regions may be formed in the substrate 100 on one side of the peripheral circuit element PT. The source/drain regions may include or may be doped with impurities. The source/drain contacts SDCT may be connected to the source/drain regions.

In some embodiments, a bottom surface SDCT_BS of the source/drain contacts SDCT may be on the same plane as a bottom surface WCT_BS of the word line contact WCT.

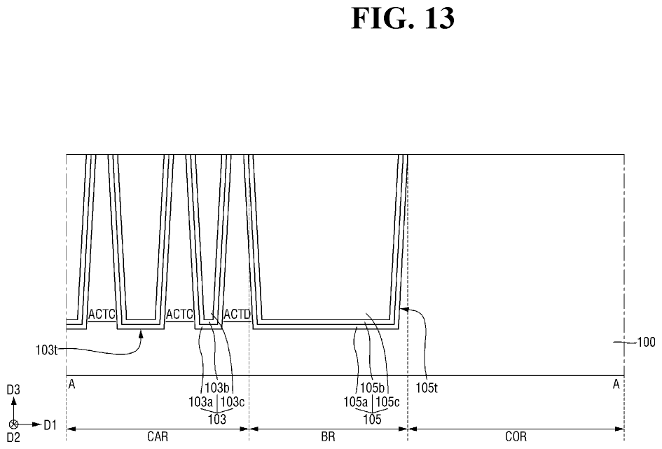

A method of manufacturing a semiconductor memory device according to some embodiments of the present disclosure will be described below with reference to FIGS. 13 to 20.

FIGS. 13 to 20 are intermediate stage diagrams for explaining the method of manufacturing the semiconductor memory device according to some embodiments.

Referring to FIG. 13, a substrate 100 may be provided. The substrate 100 may be, for example, a silicon single crystal substrate or an SOI (Silicon on Insulator) substrate. The present invention is not limited thereto. In some embodiment, the substrate 100 may include or may be formed of silicon germanium, silicon germanium on insulator (SGOI), indium antimonide, lead telluride, indium arsenide, indium phosphide, gallium arsenide or gallium antimonide.

A cell trench 103t and a connecting trench 105t may be formed inside the substrate 100. In some embodiments, a width of the cell trench 103t in the first direction D1 may be smaller than the width of the connecting trench 105t in the first direction D1, but is not limited thereto.

A cell element isolation layer 103 may be formed inside the cell trench 103t. The cell element isolation layer 103 may include a first cell liner 103a, a second cell liner 103b, and a cell buried insulating layer 103c. The first cell liner 103a may be formed along side walls and a bottom surface of the cell trench 103t. For example, the first cell liner 103a may be conformally formed on the side walls and a bottom surface of the cell trench 103t. A second cell liner 103b may be formed on the first cell liner 103a. The cell buried insulating layer 103c may be formed on the second cell liner 103b.

A connecting element isolation layer 105 may be formed inside the connecting trench 105t. The connecting element isolation layer 105 may include a first connecting liner 105a, a second connecting liner 105b, and a connecting buried insulating layer 105c. The first connecting liner 105a may be formed along side walls and a bottom surface of the connecting trench 105t. The second connecting liner 105b may be formed on the first connecting liner 105a. The connecting buried insulating layer 105c may be formed on the second connecting liner 105b.

The first cell liner 103a and the first connecting liner 105a may be formed through the same process. That is, a thickness of the first cell liner 103a and a thickness of the first connecting liner 105a may be substantially identical to each other. Similarly, the second cell liner 103b and the second connecting liner 105b may be formed through the same process. That is, a thickness of the second cell liner 103b and a thickness of the second connecting liner 105b may be substantially identical to each other. The cell buried insulating layer 103c and the connecting buried insulating layer 105c may be formed through the same process.

In some embodiments, the connecting element isolation layer 105 may define a connecting region BR. One side of the connecting region BR may be a cell region CAR, and the other side of the connecting region BR may be a core region COR. The cell element isolation layer 103 may be provided in the cell region CAR.

In some embodiments, the cell element isolation layer 103 may define a cell active region ACTC. The cell element isolation layer 103 and the connecting element isolation layer 105 may define a dummy active region ACTD. The dummy active region ACTD may be provided between the cell element isolation layer 103 and the connecting element isolation layer 105.

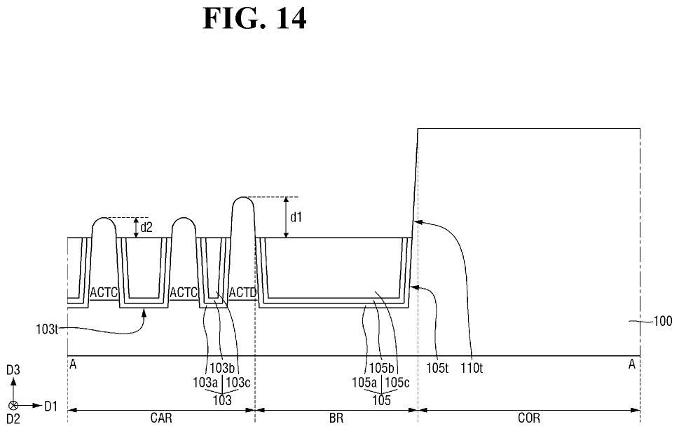

Referring to FIG. 14, a gate trench 110t may be formed. The gate trench 110t may be formed inside the substrate 100. The gate trench 110t may extend in the first direction D1. The gate trench 110t may be formed by etching the cell active region ACTC, the dummy active region ACTD, the cell element isolation layer 103, and the connecting element isolation layer 105.

The cell element isolation layer 103 and the connecting element isolation layer 105 each have etch selectivity with respect to the cell active region ACTC and the dummy active region ACTD. Therefore, the cell element isolation layer 103 and the connecting element isolation layer 105 may be more recessed than the cell active region ACTC and the dummy active region ACTD. In terms of a cross section, the cell active region ACTC may protrude beyond the upper surface of the cell element isolation layer 103. Similarly, in terms of a cross section, the dummy active region ACTD may protrude beyond the upper surface of the connecting element isolation layer 105.

In some embodiments, a first height d1 of the dummy active region ACTD protruding in the third direction D3 is greater than a second height d2 of the cell active region ACTC protruding in the third direction D3. In some embodiments, the size of the dummy active region ACTD may be greater than the size of the cell active region ACTC. That is, the dummy active region ACTD may be less recessed than the cell active region ACTC. Accordingly, the first height d1 may be greater than the second height d2. However, the technical idea of the present disclosure is not limited thereto.

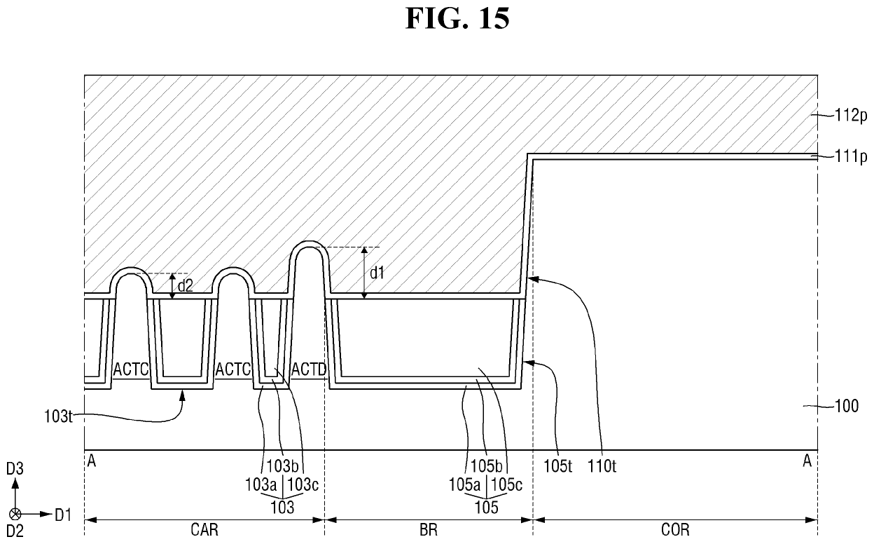

Referring to FIG. 15, a pre-gate insulating layer 111p and a pre-gate electrode 112p may be formed.

The pre-gate insulating layer 111p may be formed along the inner side walls of the gate trench 110t, the bottom surface of the gate trench 110t, and the upper side of the substrate 100. The pre-gate insulating layer 111p may cover the upper surface of the cell active region ACTC and the upper surface of the dummy active region ACTD.

The pre-gate insulating layer 111p may include or may be formed of, for example, at least one of silicon oxide, silicon nitride, silicon oxynitride, and a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The pre-gate electrode 112p may be formed on the pre-gate insulating layer 111p. The pre-gate electrode 112p may be formed on the entire surface of the substrate 100.

The pre-gate electrode 112p may include or may be formed of at least one of a metal, a metal alloy, a conductive metal nitride, a conductive metal carbonitride, a conductive metal carbide, a metal silicide, a doped semiconductor material, a conductive metal oxynitride, and a conductive metal oxide. The gate electrode 112 may include or may be formed of, for example, but is not limited to, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and combinations thereof.

Unlike the shown example, the pre-gate electrode 112p may be formed of the multiple layers. When the pre-gate electrode 112p is formed of the multiple layers, the pre-gate electrode 112p may include a barrier layer and a filling layer.

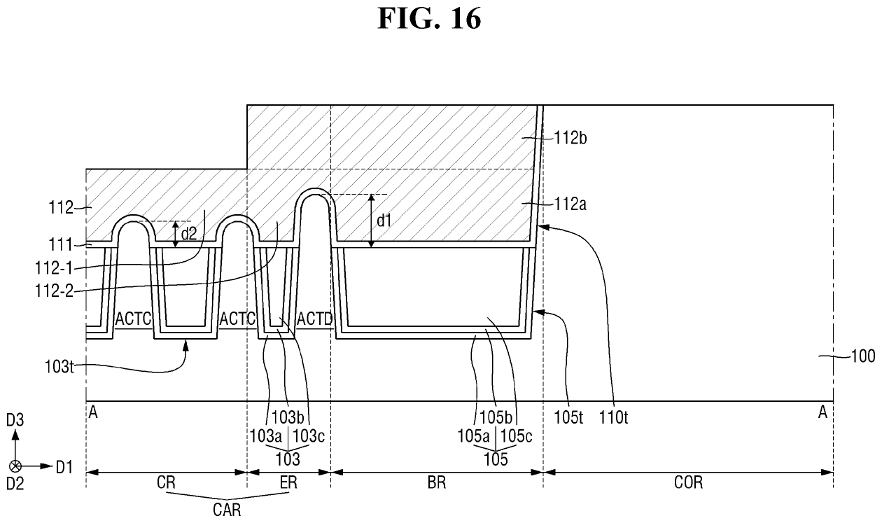

Referring to FIG. 16, a gate insulating layer 111 and a gate electrode 112 may be formed. The gate electrode 112 may include a first portion 112a and a second portion 112b. The gate insulating layer 111 may be formed by etching the pre-gate insulating layer 111p. The gate electrode 112 may be formed by etching the pre-gate electrode 112p.

First, a photoresist pattern may be formed on the pre-gate electrode 112p. The photoresist pattern may be formed along the second portion 112b of the gate electrode 112 to be formed later and the substrate of the core region COR. A part of the pre-gate electrode 112p may be removed, using the photoresist pattern as an etching mask.

After that, the photoresist pattern is removed, and the pre-gate electrode 112p and the pre-gate insulating layer 111p may be removed through an etch-back process. Therefore, the gate insulating layer 111 and the gate electrode 112 may be formed.

The gate electrode 112 may include a first region 112_1 and a second region 112_2. The first region 112_1 of the gate electrode 112 may be provided in the center region CR. The second region 112_2 of the gate electrode 112 may be provided in the edge region ER.

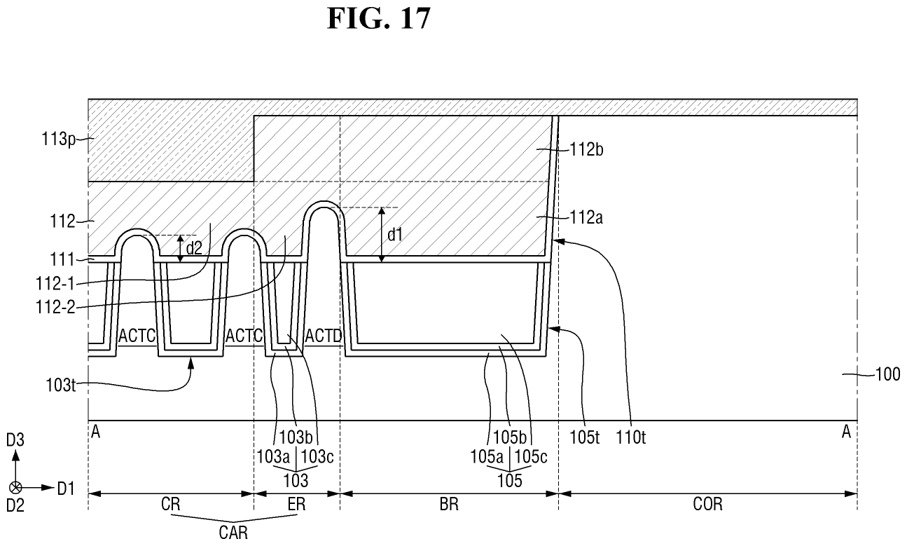

Referring to FIG. 17, a pre-gate capping conductive layer 113p may be formed on the gate electrode 112. The pre-gate capping conductive layer 113p may cover the gate electrode 112 and the substrate 100 of the core region COR. The pre-gate capping conductive layer 113p may include or may be formed of, for example, but is not limited to, polysilicon or polysilicon-germanium.

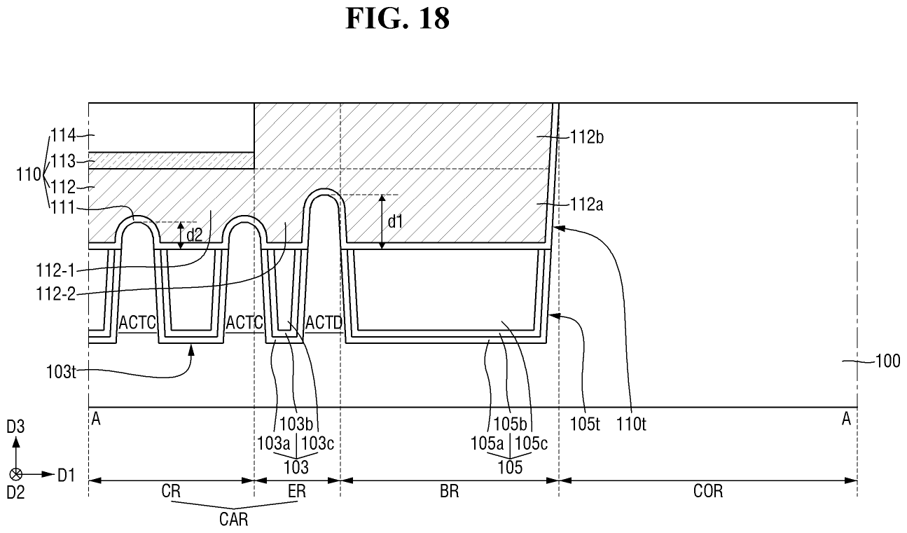

Referring to FIG. 18, gate capping layers 113 and 114 may be formed. The gate capping layers 113 and 114 may include a gate capping conductive layer 113 and a gate capping insulating layer 114.

First, the pre-gate capping conductive layer 113p may be removed through the etch-back process. The gate capping conductive layer 113 may be formed by removing the pre-gate capping conductive layer 113p. The gate capping conductive layer 113 is formed on the first portion 112a of the gate electrode 112. The gate capping conductive layer 113 does not overlap the second portion 112b of the gate electrode 112 in the third direction D3. The gate capping conductive layer 113 overlaps the second portion 112b of the gate electrode 112 in the first direction D1.

Subsequently, a gate capping insulating layer 114 may be formed on the gate capping conductive layer 113. The gate capping insulating layer 114 does not overlap the second portion 112b of the gate electrode 112 in the third direction D3. The gate capping insulating layer 114 overlaps the second portion 112b of the gate electrode 112 in the first direction D1.

The gate capping conductive layer 113 and the gate capping insulating layer 114 may be formed on the first region 112_1 of the gate electrode 112. An upper surface of the gate capping insulating layer 114 may be located in the same plane as an upper surface of the second region 112_2 of the gate electrode 112. The gate insulating layer 111, the gate electrode 112, the gate capping conductive layer 113 and the gate capping insulating layer 114 may constitute the word line structure 110.

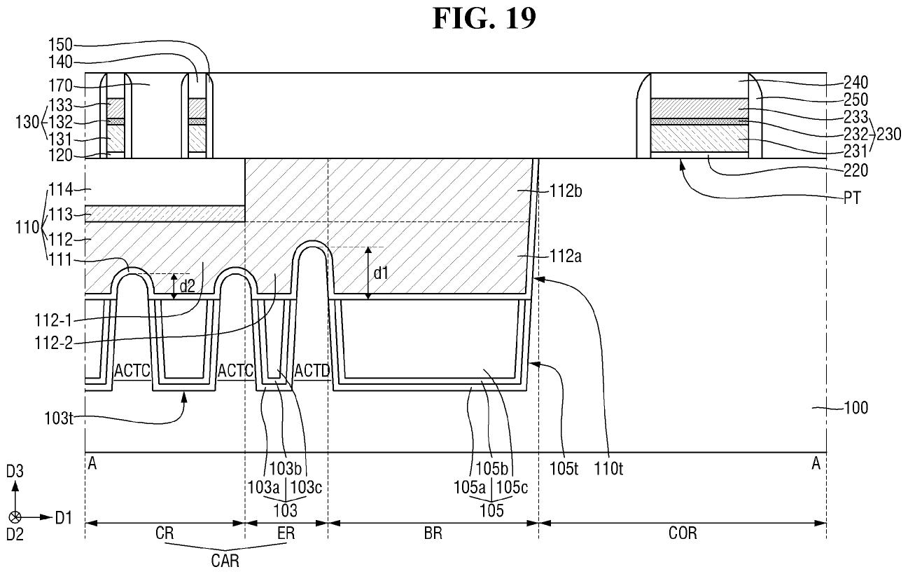

Referring to FIG. 19, a cell buffer layer 120, a bit line structure 130, a bit line capping pattern 140, a bit line spacer 150, and peripheral circuit elements may be formed on the substrate 100. The bit line structure 130 may include a bit line lower electrode 131, a bit line middle electrode 132, and a bit line upper electrode 133. The peripheral circuit element PT may include a core gate insulating layer 220, a core gate structure 230, a core gate capping pattern 240, and a core gate spacer 250. The core gate structure 230 may include first to third conductive layers 231, 232, and 233.

The cell buffer layer 120 and the core gate insulating layer 220 may be formed through the same process. The bit line lower electrode 131 and the first conductive layer 231 may be formed through the same process. The bit line middle electrode 132 and the second conductive layer 232 may be formed through the same process. The bit line upper electrode 133 and the third conductive layer 233 may be formed through the same process. The bit line capping pattern 140 and the core gate capping pattern 240 may be formed through the same process.

Therefore, the thickness of the cell buffer layer 120 and the thickness of the core gate insulating layer 220 may be substantially identical. The thickness of the bit line lower electrode 131 and the thickness of the first conductive layer 231 may be substantially identical. The thickness of the bit line middle electrode 132 and the thickness of the second conductive layer 232 may be substantially identical. The thickness of the bit line upper electrode 133 and the thickness of the third conductive layer 233 may be substantially identical. The thickness of the bit line capping pattern 140 and the thickness of the core gate capping pattern 240 may be substantially identical.

A fence pattern 170 may be formed on the substrate 100. The fence pattern 170 may be formed on the cell element isolation layer 103 and the connecting element isolation layer 105. The fence pattern 170 may be formed on the word line structure 110. The fence pattern 170 may be formed between the bit line structures 130. The fence pattern 170 may be formed on side walls of the peripheral circuit element PT.

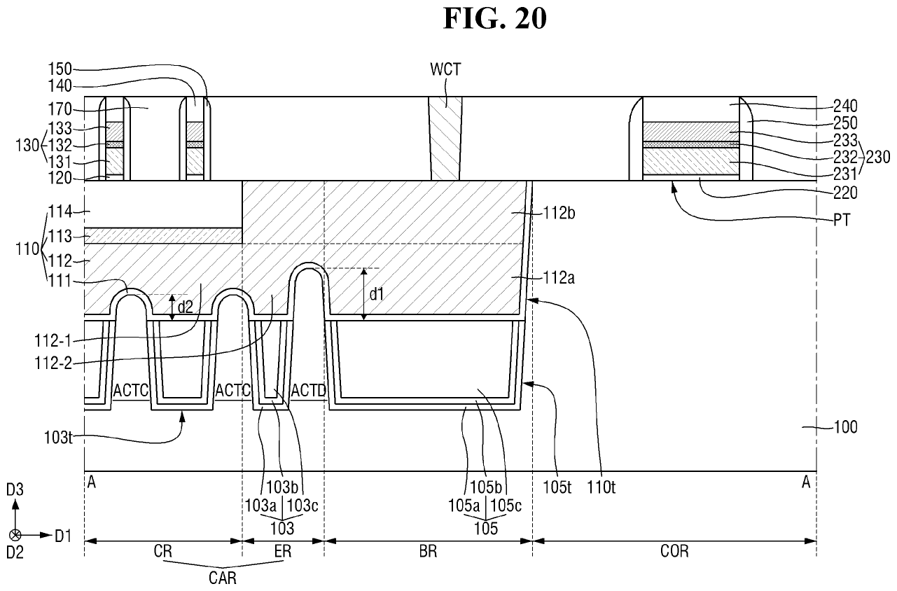

Referring to FIG. 20, a word line contact WCT may be formed. The word line contact WCT penetrates the fence pattern 170, and may be connected to the gate electrode 112. The word line contact WCT may be formed on the second portion 112b of the gate electrode 112. For example, the word line contact WCT may contact an upper surface of the second portion 112b of the gate electrode 112. A control signal may be supplied to a word line (WL of FIG. 2) through the word line contact WCT. The word line contact WCT does not contact the first portion 112a of the gate electrode 112. The word line contact WCT may not overlap the gate capping layers 113 and 114 in the first direction D1. However, the technical idea of the present disclosure is not limited thereto. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

In the semiconductor memory device according to some embodiments, the second portion 112b of the gate electrode 112 overlaps the dummy active region ACTD in the third direction D3. Also, the second portion 112b of the gate electrode 112 overlaps the gate capping layers 113 and 114 in the first direction D1. Also, the upper surface of the second portion 112b of the gate electrode 112 is located on the same plane as the upper surfaces of the gate capping layers 113 and 114. As the gate electrode 112 has the structure as described above, the gate electrode 112 may not be electrically shorted by the dummy active region ACTD. That is, a semiconductor memory device with improved reliability can be implemented.

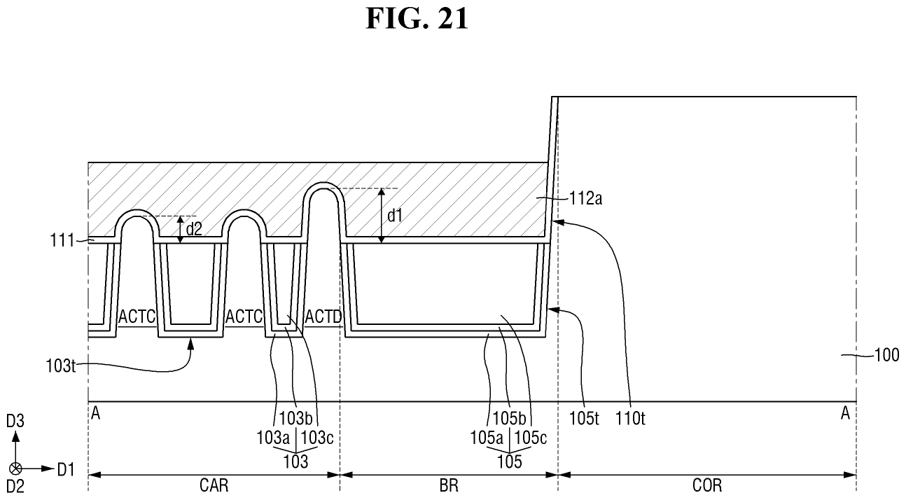

Hereinafter, a method of manufacturing a semiconductor memory device according to some embodiments of the present disclosure will be described with reference to FIGS. 15 and 21 to 25. For convenience of explanation, the explanation will focus on points different from those explained using FIGS. 13 to 20. FIGS. 21 to 25 are intermediate stage diagrams for explaining the method of manufacturing the semiconductor memory device according to some embodiments.

Referring to FIG. 15, a pre-gate insulating layer 111p and a pre-gate electrode 112p may be formed. The pre-gate insulating layer 111p may be formed along the inner side walls of the gate trench 110t, the bottom surface of the gate trench 110t, and the upper surface of the substrate 100. The pre-gate insulating layer 111p may cover the upper surface of the cell active region ACTC and the upper surface of the dummy active region ACTD.

Next, referring to FIG. 21, the first portion 120a of the gate electrode 112 may be formed through an etch-back process. The gate insulating layer 111 may be formed through an etch-back process. The first portion 120a of the gate electrode 112 may cover a part of the cell active region ACTC and a part of the dummy active region ACTD.

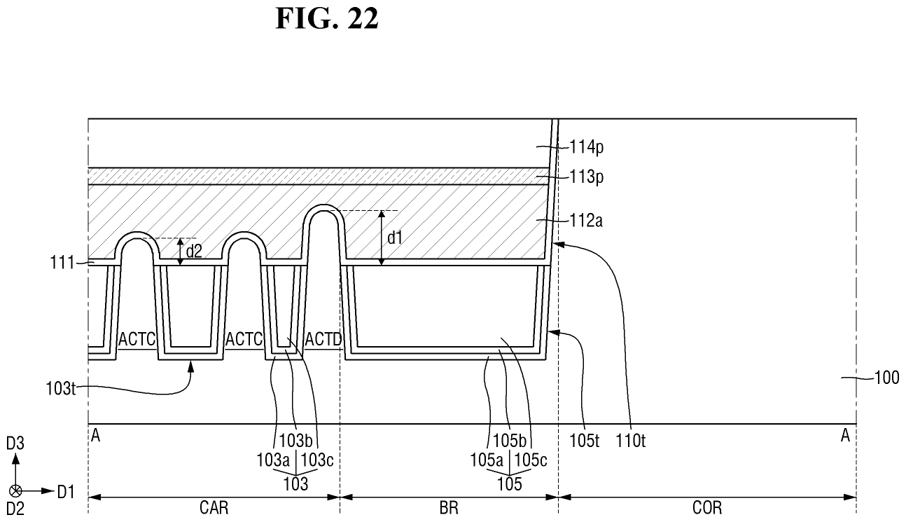

Referring to FIG. 22, a pre-gate capping conductive layer 113p and a pre-gate capping insulating layer 114p may be formed on the first portion 120a of the gate electrode 112. The pre-gate capping conductive layer 113p may be formed on the first portion 120a of the gate electrode 112, and the pre-gate capping insulating layer 114p may be formed on the pre-gate capping conductive layer 113p. An upper surface of the pre-gate capping insulating layer 114p may be located in the same plane as the upper surface of the substrate 100. The pre-gate capping insulating layer 114p may include or may be formed of, for example, at least one of silicon nitride (SiN), silicon oxynitride (SiON), silicon oxide (SiO₂), silicon carbonitride (SiCN), silicon oxycarbonitride (SiOCN), and combinations thereof.

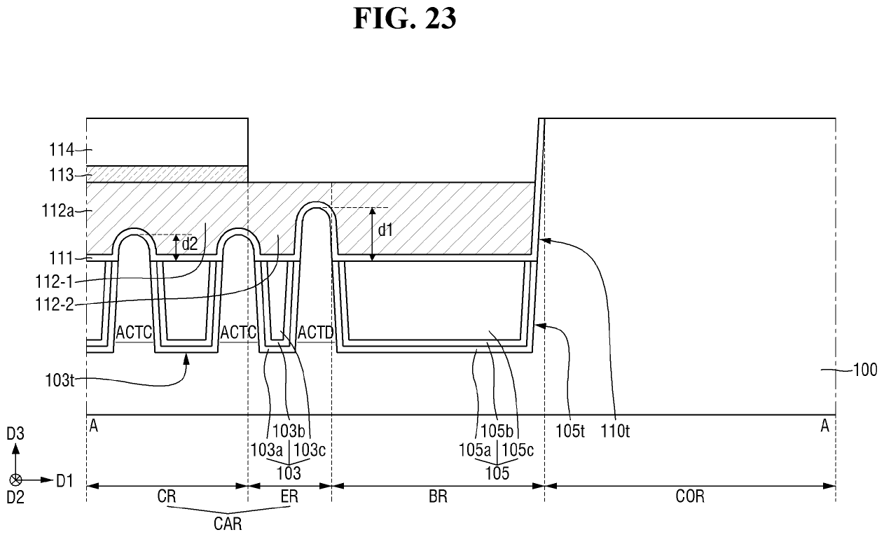

Referring to FIG. 23, the gate capping conductive layer 113 and the gate capping insulating layer 114 may be formed, by removing the pre-gate capping conductive layer 113p and the pre-gate capping insulating layer 114p. The gate capping conductive layer 113 and the gate capping insulating layer 114 may be formed on the first region 112_1 of the gate electrode 112. The upper surface of the second region 112_2 of the gate electrode 112 may be exposed, by removing the pre-gate capping conductive layer 113p and the pre-gate capping insulating layer 114p. The upper surface of the first portion 112a of the gate electrode 112 on the connecting region BR may be removed, by exposing the pre-gate capping conductive layer 113p and the pre-gate capping insulating layer 114p.

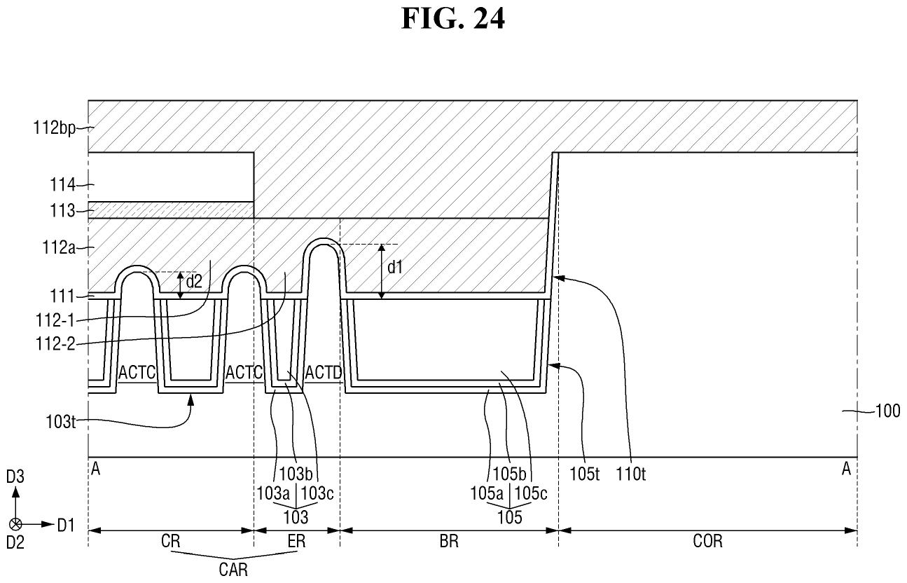

Referring to FIG. 24, a second portion 112bp of the pre-gate electrode may be formed on the first portion 112a of the gate electrode 112, the gate capping insulating layer 114, and the substrate 100. The second portion 112bp of the pre-gate electrode may be formed of the same material as or a different material from the first portion 112a of the gate electrode 112.

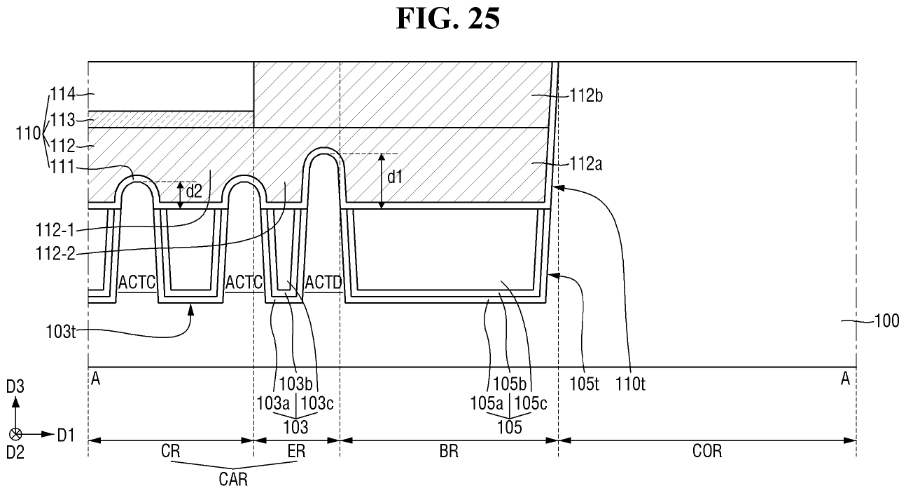

Referring to FIG. 25, the second portion 112bp of the pre-gate electrode may be removed through an etch-back process. The second portion 112b of the gate electrode 112 may be formed by removing the second portion 112bp of the pre-gate electrode. An upper surface of the second portion 112b of the gate electrode 112 may be located in the same plane as an upper surface of the gate capping insulating layer 114. The second portion 112b of the gate electrode 112 may overlap the dummy active region ACTD in the third direction D3. The second portion 112b of the gate electrode 112 may overlap the gate capping conductive layer 113 and the gate capping insulating layer 114 in the first direction D1.

Thereafter, although not shown, a bit line structure 130, a peripheral circuit element PT, and a word line contact WCT may be formed.

In concluding the detailed description, those skilled in the art will appreciate that many variations and modifications may be made to the embodiments without substantially departing from the principles of the present disclosure. Therefore, the disclosed embodiments of the disclosure are used in a generic and descriptive sense only and not for purposes of limitation.

What is claimed is:

1. A semiconductor memory device comprising:
a substrate which includes a cell region and a connecting region around the cell region;
a cell active region which is defined by a cell element isolation layer in the cell region;
a connecting element isolation layer which is placed in the connecting region;
a word line structure which is buried in the cell region and the connecting region and extends in a first horizontal direction;
a bit line structure which is disposed on the substrate and extends in a second horizontal direction intersecting the first horizontal direction;
a capacitor structure disposed on the cell region and connected to the cell active region; and
a dummy active region disposed between the cell element isolation layer and the connecting element isolation layer,
wherein the word line structure includes a gate electrode and a gate capping layer,
wherein the gate electrode includes:
a first portion that does not overlap the gate capping layer in the first horizontal direction, and
a second portion that is disposed on the first portion and overlaps the gate capping layer in the first horizontal direction, and
wherein the second portion overlaps the dummy active region in a vertical direction intersecting the first and second horizontal directions.

2. The semiconductor memory device of claim 1,
wherein at least a part of the second portion of the gate electrode is buried in the connecting region.

3. The semiconductor memory device of claim 1,
wherein a first height of a first upper portion of the dummy active region is higher than a second height of a second upper portion of the cell active region,
wherein the first upper portion of the dummy active region and the second upper portion of the cell active region are surrounded by the gate electrode, and
wherein the first and second heights are measured in the vertical direction relative to a bottom surface of the gate electrode.

4. The semiconductor memory device of claim 1,
wherein at least a part of the dummy active region overlaps the gate capping layer in the first horizontal direction.

5. The semiconductor memory device of claim 1,
wherein the dummy active region does not overlap the gate capping layer in the first horizontal direction.

6. The semiconductor memory device of claim 1,
wherein the gate capping layer includes:
a gate capping conductive layer, and
a gate capping insulating layer on the gate capping conductive layer.

7. The semiconductor memory device of claim 1, further comprising:
a word line contact which is disposed on the connecting region and contacts the second portion of the gate electrode.

8. The semiconductor memory device of claim 1,
wherein a part of the second portion of the gate electrode overlaps the cell active region in the vertical direction.

9. The semiconductor memory device of claim 1,
wherein an upper surface of the second portion of the gate electrode is coplanar with an upper surface of the gate capping layer.

10. The semiconductor memory device of claim 1,
wherein the first portion and the second portion are formed of different materials from each other.

11. The semiconductor memory device of claim 1,
wherein the dummy active region does not completely overlap the gate capping layer in the vertical direction.

12. A semiconductor memory device comprising:
a substrate which includes an edge region, and a center region defined by the edge region;
a cell active region which is disposed on the center region and defined by a cell element isolation layer;
a plurality of word line structures which are buried in the substrate, extend in a first horizontal direction, and are spaced apart in a second horizontal direction intersecting the first horizontal direction;
a plurality of bit line structures which are disposed on the substrate, extend in the second horizontal direction, and are spaced apart in the first horizontal direction;
a capacitor structure disposed on the substrate and connected to the cell active region; and
a dummy active region disposed on the edge region,
wherein each word line structure of the plurality of word line structures includes:
a gate electrode including a first region disposed on the center region and a second region disposed on the edge region, and
a gate capping layer disposed on the first region of the gate electrode,
wherein an upper surface of the second region of the gate electrode is coplanar with an upper surface of the gate capping layer, and
wherein the second region of the gate electrode overlaps the dummy active region in a vertical direction that intersects the first and second horizontal directions.

13. The semiconductor memory device of claim 12,
wherein the gate capping layer includes:
a gate capping conductive layer, and
a gate capping insulating layer on the gate capping conductive layer.

14. The semiconductor memory device of claim 12,
wherein at least a part of the dummy active region overlaps the gate capping layer in the first horizontal direction.

15. The semiconductor memory device of claim 12,
wherein the dummy active region does not overlap the gate capping layer in the first horizontal direction.

16. The semiconductor memory device of claim 12,
wherein the dummy active region does not completely overlap the gate capping layer in the vertical direction.

17. A semiconductor memory device comprising:
a substrate which includes a cell region, a core region defined around the cell region, and a connecting region between the cell region and the core region, the cell region including an edge region, and a center region defined by the edge region;
a cell element isolation layer disposed on the center region of the cell region;
a connecting element isolation layer in the connecting region;
a word line structure which is buried in the cell region and the connecting region and extends in a first horizontal direction,
wherein the word line structure includes a gate electrode, a gate capping conductive layer, and a gate capping insulating layer, and
wherein the gate electrode includes:
a first portion that does not overlap the gate capping conductive layer and the gate capping insulating layer in the first horizontal direction, and
a second portion that overlaps the gate capping conductive layer and the gate capping insulating layer in the first horizontal direction;
a bit line structure which is disposed on the substrate and extends in a second horizontal direction intersecting the first horizontal direction;
a capacitor structure connected to the active region and disposed on the cell region;
a peripheral circuit element disposed on the core region;
a word line contact which contacts the second portion of the gate electrode and is connected to the peripheral circuit element on the connecting region, and does not completely overlap the gate capping conductive layer in the first horizontal direction; and
a dummy active region disposed between the cell element isolation layer and the connecting element isolation layer on the edge region, and a cell active region except the dummy active region on the center region,
wherein the gate capping conductive layer and the gate capping insulating layer are not disposed in the edge region, and
wherein the second portion overlaps the dummy active region in a vertical direction intersecting the first and second horizontal directions.

18. The semiconductor memory device of claim 17,
wherein at least a part of the second portion of the gate electrode is buried inside the connecting region.

19. The semiconductor memory device of claim 17,
wherein the second portion of the gate electrode overlaps a part of the cell active region in the vertical direction.

20. The semiconductor memory device of claim 17,
wherein an upper surface of the second portion of the gate electrode is coplanar with an upper surface of the gate capping insulating layer.
